(19) United States
(12) Patent Application Publication
(10) Pub. No.: US 2024/0030331 A1
(43) Pub. Date: Jan. 25, 2024

(54) SEMICONDUCTOR DEVICE AND METHOD FOR MANUFACTURING THE SAME

(71) Applicant: INNOSCIENCE (SUZHOU) TECHNOLOGY CO., LTD., Suzhou, Jiangsu (CN)

(72) Inventors: Yang LIU, Suzhou City (CN); Weixing DU, Suzhou City (CN); Pan WANG, Suzhou City (CN); Jheng-Sheng YOU, Suzhou City (CN)

(21) Appl. No.: 17/603,334

(22) PCT Filed: Aug. 6, 2021
(86) PCT No.: PCT/CN2021/111307

§ 371 Date: Oct. 12, 2021

(51) Int. Cl. H01L 29/778; H01L 29/20; H01L 23/31; H01L 29/66

(52) U.S. Cl. CPC H01L 29/7786; H01L 29/2003; H01L 23/3171; H01L 29/66462

(57) ABSTRACT

A semiconductor device includes a first nitride-based semiconductor layer, a second nitride-based semiconductor layer, a doped nitride-based semiconductor layer, a gate electrode, a first oxynitride dielectric layer, a first passivation layer, a second oxynitride dielectric layer, a second passivation layer, and a S/D electrode. The first oxynitride dielectric layer is disposed over the second nitride-based semiconductor layer and conformally covers the doped nitride-based semiconductor layer and the gate electrode. The first passivation layer is disposed on the first oxynitride dielectric layer and in contact with the first oxynitride dielectric layer. The second oxynitride dielectric layer is disposed on the first passivation layer and in contact with the first passivation layer. The second passivation layer is disposed on the second oxynitride dielectric layer and in contact with the second oxynitride dielectric layer. The S/D electrode penetrates makes contact with the second nitride-based semiconductor layer.

### FIELD OF THE DISCLOSURE

The present disclosure generally relates to a nitride-based semiconductor device. More specifically, the present disclosure relates to a nitride-based semiconductor device having a multilayer structure protecting a gate electrode.

### BACKGROUND OF THE DISCLOSURE

In recent years, intense research on high-electron-mobility transistors (HEMTs) has been prevalent, particularly for high power switching and high frequency applications. III-nitride-based HEMTs utilize a heterojunction interface between two materials with different bandgaps to form a quantum well-like structure, which accommodates a two-dimensional electron gas (2DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET). However, during the manufacturing process of III-nitride devices, oxygen diffusion may cause a leakage current issue, degrading the electrical properties of the device. Therefore, there is a need to improve device performance regarding this issue.

### SUMMARY OF THE DISCLOSURE

In accordance with one aspect of the present disclosure, a semiconductor device is provided. A semiconductor device includes a first nitride-based semiconductor layer, a second nitride-based semiconductor layer, a doped nitride-based semiconductor layer, a gate electrode, a first oxynitride dielectric layer, a first passivation layer, a second oxynitride dielectric layer, a second passivation layer, and a source/drain (S/D) electrode. The second nitride-based semiconductor layer is disposed on the first nitride-based semiconductor layer and has a bandgap greater than a bandgap of the first nitride-based semiconductor layer. The doped nitride-based semiconductor layer is disposed over the second nitride-based semiconductor layer. The gate electrode is disposed on the doped nitride-based semiconductor layer to form a protruding profile with the doped nitride-based semiconductor layer. The first oxynitride dielectric layer is disposed over the second nitride-based semiconductor layer and conformally covers the doped nitride-based semiconductor layer and the gate electrode. The first passivation layer is disposed on the first oxynitride dielectric layer and in contact with the first oxynitride dielectric layer. The second oxynitride dielectric layer is disposed on the first passivation layer and in contact with the first passivation layer. The second passivation layer is disposed on the second oxynitride dielectric layer and in contact with the second oxynitride dielectric layer. The source/drain (S/D) electrode penetrates the first and second oxynitride dielectric layers and the first and second passivation layers to make contact with the second nitride-based semiconductor layer.

In accordance with one aspect of the present disclosure, a method for manufacturing a semiconductor device is provided. The method includes steps as follows. A first nitride-based semiconductor layer is formed. A second nitride-based semiconductor layer is formed on the first nitride-based semiconductor layer. A doped nitride-based semiconductor layer is formed over the second nitride-based semiconductor layer. A gate electrode is formed on the doped nitride-based semiconductor layer. A first oxynitride dielectric layer is formed on the second nitride-based semiconductor layer to conformally cover the second nitride-based semiconductor layer, the doped nitride-based semiconductor layer, and the gate electrode. The first passivation layer is formed conformally on the first oxynitride dielectric layer. The second oxynitride dielectric layer is formed on the first passivation layer. The second passivation layer is formed on the second oxynitride dielectric layer. Portions of the first and second oxynitride dielectric layers and first and second passivation layers are removed to form an ohmic contact hole which exposes the second nitride-based semiconductor layer. The ohmic contact hole is filled with a source/drain (S/D) electrode.

In accordance with one aspect of the present disclosure, a semiconductor device is provided. A semiconductor device includes a first nitride-based semiconductor layer, a second nitride-based semiconductor layer, a doped nitride-based semiconductor layer, a gate electrode, a multilayer structure, and a source/drain electrode. The second nitride-based semiconductor layer is disposed on the first nitride-based semiconductor layer and has a bandgap greater than a bandgap of the first nitride-based semiconductor layer. The doped nitride-based semiconductor layer is disposed over the second nitride-based semiconductor layer. The gate electrode is disposed on the doped nitride-based semiconductor layer. The multilayer structure is disposed on the second nitride-based semiconductor layer and conformally covers the doped nitride-based semiconductor layer and the gate electrode. The multilayer structure includes a first oxynitride dielectric layer, a first passivation layer, a second oxynitride dielectric layer, and a second passivation layer. The first oxynitride dielectric layer is stacked on the second nitride-based semiconductor layer. The first passivation layer is stacked on the first oxynitride dielectric layer. The second oxynitride dielectric layer is stacked on the first passivation layer. The second passivation layer is stacked on the second oxynitride dielectric layer. The multilayer structure has an oxygen concentration increases and then decreases along a vertical direction. The source/drain electrode penetrates the multilayer structure to make contact with the second nitride-based semiconductor layer.

By the above configuration, the first passivation layer of the multilayer structure can block oxygen diffusion from the second oxynitride dielectric layer to the first oxynitride dielectric layer. Moreover, there are two oxygen peaks in the graph of the oxygen concentration versus the thickness of the semiconductor device. These two peaks are spaced apart by the first passivation layer, which means the first passivation layer can effectively block the oxygen downward diffusing from the second oxynitride dielectric layer. As such, no stronger oxygen peak occurs in the multilayer structure.

### BRIEF DESCRIPTION OF THE DRAWINGS

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIG. 1A is a vertical cross-sectional view of a semiconductor device according to some embodiments of the present disclosure;

FIG. 1B is an enlarged vertical cross-sectional view of a region in FIG. 1A according to some embodiments of the present disclosure;

FIG. 1C shows an energy-dispersive X-ray spectroscopy result of the semiconductor device along a distance in FIG. 1B;

FIG. 2A, FIG. 2B, FIG. 2C, FIG. 2D, and FIG. 2E show different stages of a method for manufacturing a nitride-based semiconductor device according to some embodiments of the present disclosure;

FIG. 3 is a cross-sectional view of a semiconductor device according to some embodiments of the present disclosure; and

FIG. 4 is a cross-sectional view of a semiconductor device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “on,” “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Further, it is noted that the actual shapes of the various structures depicted as approximately rectangular may, in actual device, be curved, have rounded edges, have somewhat uneven thicknesses, etc. due to device fabrication conditions. The straight lines and right angles are used solely for convenience of representation of layers and features.

In the following description, semiconductor devices/dies/packages, methods for manufacturing the same, and the likes are set forth as preferred examples. It will be apparent to those skilled in the art that modifications, including additions and/or substitutions may be made without departing from the scope and spirit of the present disclosure. Specific details may be omitted so as not to obscure the present disclosure; however, the disclosure is written to enable one skilled in the art to practice the teachings herein without undue experimentation.

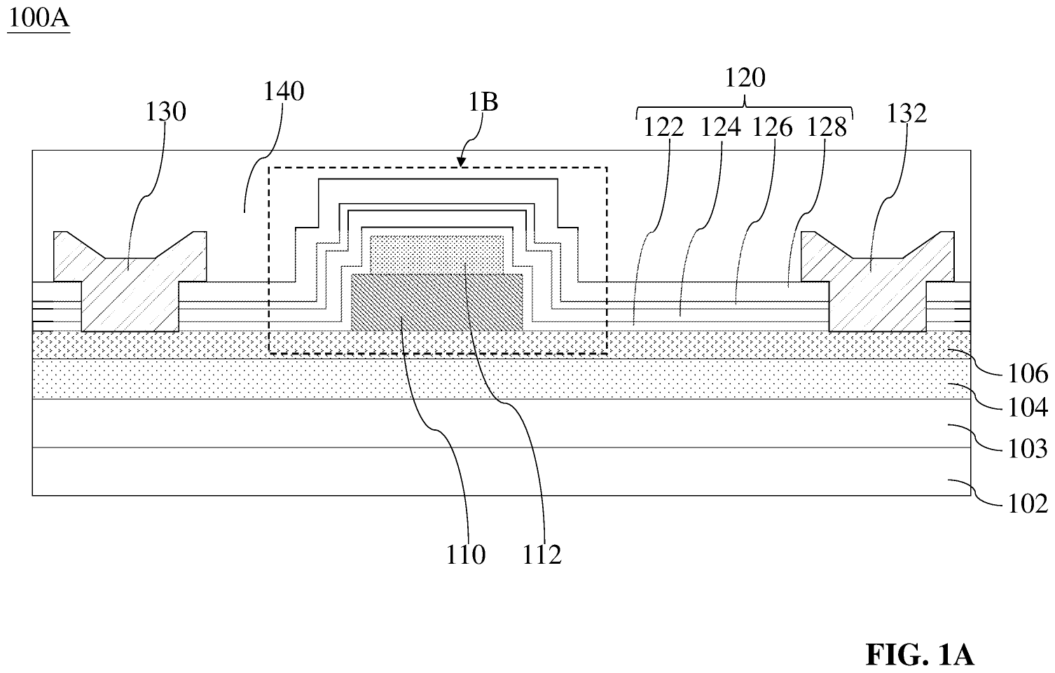

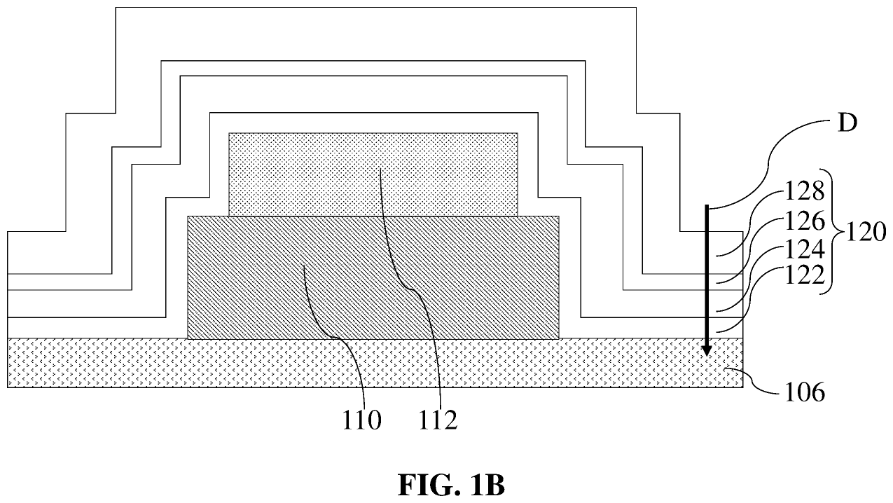

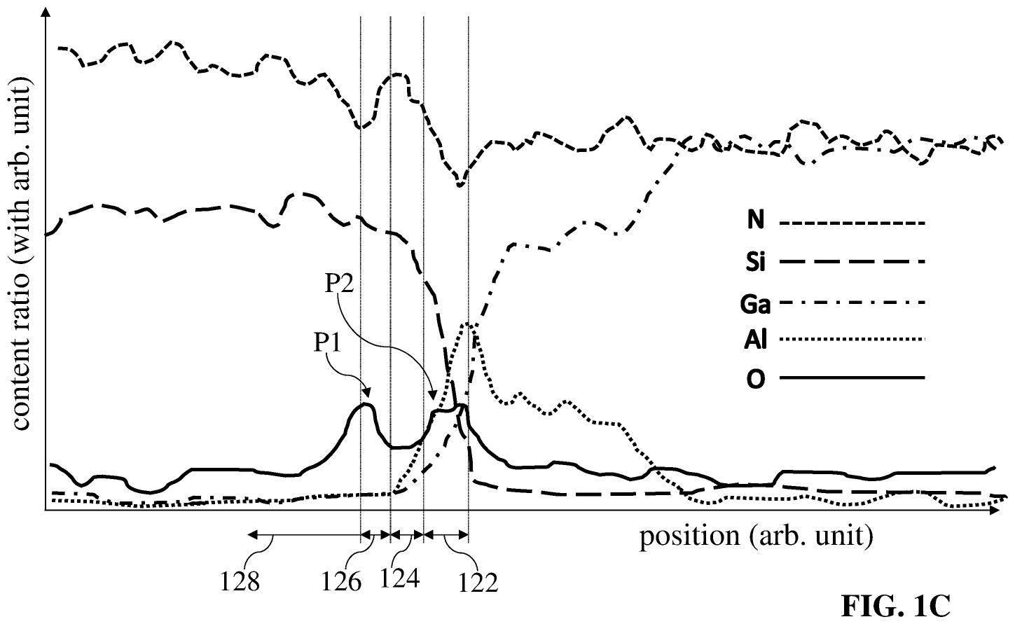

FIG. 1A is a vertical cross-sectional view of a semiconductor device 100A according to some embodiments of the present disclosure. The semiconductor device 100A includes a substrate 102, a buffer layer 103, nitride-based semiconductor layers 104 and 106, a doped nitride-based semiconductor layer 110, a gate electrode 112, conductive electrodes 110 and 112, a multilayer structure 120, and a passivation layer 140.

The substrate 102 may be a semiconductor substrate. The exemplary materials of the substrate 102 can include, for example but are not limited to, Si, SiGe, SiC, gallium arsenide, p-doped Si, n-doped Si, sapphire, semiconductor on insulator, such as silicon on insulator (SOI), or other suitable substrate materials. In some embodiments, the substrate 102 can include, for example, but is not limited to, group III elements, group IV elements, group V elements, or combinations thereof (e.g., III-V compounds). In other embodiments, the substrate 102 can include, for example but is not limited to, one or more other features, such as a doped region, a buried layer, an epitaxial (epi) layer, or combinations thereof.

The buffer layer 103 can be disposed over the substrate 102. The buffer layer 103 can be disposed between the substrate 102 and the nitride-based semiconductor layer 104. The buffer layer 103 can be configured to reduce lattice and thermal mismatches between the substrate 102 and the nitride-based semiconductor layer 104, thereby curing defects due to the mismatches/difference. The buffer layer 103 may include a III-V compound. The III-V compound can include, for example but are not limited to, aluminum, gallium, indium, nitrogen, or combinations thereof. Accordingly, the exemplary materials of the buffer layer 103 can further include, for example but are not limited to, GaN, AlN, AlGaN, InAlGaN, or combinations thereof. In some embodiments, the semiconductor device 100A may further include a nucleation layer (not shown). The nucleation layer may be formed between the substrate 102 and the buffer layer 103. The nucleation layer can be configured to provide a transition to accommodate a mismatch/difference between the substrate 102 and a III-nitride layer of the buffer layer. The exemplary material of the nucleation layer can include, for example but is not limited to AlN or any of its alloys.

The nitride-based semiconductor layer 104 is disposed over the substrate 102 and the buffer layer 103. The nitride-based semiconductor layer 106 is disposed on the nitride-based semiconductor layer 104. The exemplary materials of the nitride-based semiconductor layer 104 can include, for example but are not limited to, nitrides or group III-V compounds, such as GaN, AlN, InN, InₓAl_{y}Ga_{(1-x-y)}N where x+y≤1, Al_{y}Ga_{(1-y)}N where y≤1. The exemplary materials of the nitride-based semiconductor layer 106 can include, for example but are not limited to, nitrides or group III-V compounds, such as GaN, AlN, InN, InₓAl_{y}Ga_{(1-x-y)}N where x+y≤1, Al_{y}Ga_{(1-y)}N where y≤1.

The exemplary materials of the nitride-based semiconductor layers 104 and 106 are selected such that the nitride-based semiconductor layer 106 has a bandgap (i.e., forbidden band width) greater than a bandgap of the nitride-based semiconductor layer 104, which causes electron affinities thereof different from each other and forms a heterojunction therebetween. For example, when the nitride-based semiconductor layer 104 is an undoped GaN layer having a bandgap of approximately 3.4 eV, the nitride-based semiconductor layer 106 can be selected as an AlGaN layer having bandgap of approximately 4.0 eV. As such, the nitride-based semiconductor layers 104 and 106 can serve as a channel layer and a barrier layer, respectively. A triangular well potential is generated at a bonded interface between the channel and barrier layers, so that electrons accumulate in the triangular well, thereby generating a two-dimensional electron gas (2DEG) region adjacent to the heterojunction. Accordingly, the semiconductor device 100A is available to include at least one GaN-based high-electron-mobility transistor (HEMT).

The doped nitride-based semiconductor layer 110 is disposed on/above the nitride-based semiconductor layer 106. The gate electrode 112 is disposed/stacked on the doped nitride-based semiconductor layer 110. the gate electrode 112 can form a protruding profile with the doped nitride-based semiconductor layer 110. A width of the doped nitride-based semiconductor layer 110 is substantially the same as a width of the gate electrode 112. The doped nitride-based semiconductor layer 110 is disposed between the nitride-based semiconductor layer 106 and the gate electrode 112. The doped nitride-based semiconductor layer 110 covers a portion of the nitride-based semiconductor layer 106.

In the exemplary illustration of FIG. 1A, the semiconductor device 100A is an enhancement mode device, which is in a normally-off state when the gate electrode 112 is at approximately zero bias. Specifically, the doped nitride-based semiconductor layer 110 may create at least one p-n junction with the nitride-based semiconductor layer 106 to deplete the 2DEG region, such that at least one zone of the 2DEG region corresponding to a position below the corresponding the gate electrode 112 has different characteristics (e.g., different electron concentrations) than the rest of the 2DEG region and thus is blocked. Due to such mechanism, the semiconductor device 100A has a normally-off characteristic. In other words, when no voltage is applied to the gate electrode 112 or a voltage applied to the gate electrode 112 is less than a threshold voltage (i.e., a minimum voltage required to form an inversion layer below the gate electrode 112), the zone of the 2DEG region below the gate electrode 112 is kept blocked, and thus no current flows therethrough.

In some embodiments, the doped nitride-based semiconductor layer 110 can be omitted, such that the semiconductor device 100A is a depletion-mode device, which means the semiconductor device 100A in a normally-on state at zero gate-source voltage.

The doped nitride-based semiconductor layer 110 can be a p-type doped III-V semiconductor layer. The exemplary materials of the doped nitride-based semiconductor layer 110 can include, for example but are not limited to, p-doped group III-V nitride semiconductor materials, such as p-type GaN, p-type AlGaN, p-type InN, p-type AlInN, p-type InGaN, p-type AlInGaN, or combinations thereof. In some embodiments, the p-doped materials are achieved by using a p-type impurity, such as Be, Mg, Zn, Cd, and Mg. In some embodiments, the nitride-based semiconductor layer 104 includes undoped GaN and the nitride-based semiconductor layer 106 includes AlGaN, and the doped nitride-based semiconductor layer 110 is a p-type GaN layer which can bend the underlying band structure upwards and to deplete the corresponding zone of the 2DEG region, so as to place the semiconductor device 100A into an off-state condition.

The exemplary materials of the gate electrode 112 may include metals or metal compounds. The gate electrode 112 may be formed as a single layer, or plural layers of the same or different compositions. The exemplary materials of the metals or metal compounds can include, for example but are not limited to, W, Au, Pd, Ti, Ta, Co, Ni, Pt, Mo, TiN, TaN, metal alloys or compounds thereof, or other metallic compounds.

The multilayer structure 120 is disposed on the nitride-based semiconductor layer 106. The multilayer structure 120 conformally covers the doped nitride-based semiconductor layer 110 and the gate electrode 112. The multilayer structure 120 includes an oxynitride dielectric layer 122, a passivation layer 124, an oxynitride dielectric layer 126, and a passivation layer 128.

The oxynitride dielectric layer 122, the passivation layer 124, the oxynitride dielectric layer 126, and the passivation layer 128 are formed to protect the nitride-based semiconductor layer 106 during the manufacturing process thereof.

In a practice case, as considered of the process requirements (or the cost), a protection layer on a gate electrode needs to be formed to contain oxygen. For a HEMT device having a single gate protection dielectric layer, its nitride-based semiconductor layer may be damaged at the stage for manufacturing the gate protection dielectric layer. For example, once the gate protection dielectric layer is to be formed as a thick layer containing oxygen, the oxygen inside would diffuse to the nitride-based semiconductor layer during the manufacturing stage, which causes electrical damage to the device. Oxygen diffusing into a nitride-based channel layer may bring a leakage current issue.

The oxynitride dielectric layer 122, the passivation layer 124, the oxynitride dielectric layer 126, and the passivation layer 128 are formed on the nitride-based semiconductor layer 106 in sequence. The material and thickness configuration of them can achieve the protection to the nitride-based semiconductor layer 106 during the manufacturing process.

FIG. 1B is an enlarged vertical cross-sectional view of a region 1B in FIG. 1A according to some embodiments of the present disclosure. The oxynitride dielectric layer 122 is disposed over the nitride-based semiconductor layer 106. The oxynitride dielectric layer 120 conformally covers the doped nitride-based semiconductor layer 110 and the gate electrode 112. The passivation layer 124 is disposed on the oxynitride dielectric layer 122. The passivation layer 124 is in contact with the oxynitride dielectric layer 122. The oxynitride dielectric layer 126 is disposed on the passivation layer 124. The oxynitride dielectric layer 126 is in contact with the passivation layer 124. The passivation layer 128 is disposed on the oxynitride dielectric layer 126. The passivation layer 128 is in contact with the oxynitride dielectric layer 126.

Each pair of the adjacent layers among the oxynitride dielectric layer 122, the passivation layer 124, the oxynitride dielectric layer 126, and the passivation layer 128 are formed by using different materials, so as to block the oxygen diffusion to the nitride-based semiconductor layer 106. In some embodiments, exemplary materials of the oxynitride dielectric layer 122 can include, for example but are not limited to, Si₃N₄, SiO₂, Al₂O₃, AlOₓN, SiO_{y}N, or combinations thereof. In some embodiments, exemplary materials of the passivation layer 124 can include, for example but are not limited to, Si₃N₄, SiO₂, Al₂O₃, AlOₓN, SiO_{y}N, or combinations thereof. In some embodiments, exemplary materials of the oxynitride dielectric layer 126 can include, for example but are not limited to, Si₃N₄, SiO₂, Al₂O₃, AlOₓN, SiO_{y}N, or combinations thereof. In some embodiments, exemplary materials of the passivation layer 124 can include, for example but are not limited to, Si₃N₄, SiO₂, Al₂O₃, AlOₓN, SiO_{y}N, or combinations thereof.

To illustrate, FIG. 1C shows an energy-dispersive X-ray (EDX) spectroscopy result of the semiconductor device 100A along a distance D in FIG. 1B. The X-axis represents the downward position (i.e., distance/thinness/depth) from the passivation layer 128 with arb unit. The Y-axis represents the content ratio of the contained elements in the layers with arb unit. The EDX spectroscopy result in FIG. 1C can serve as a graph of an oxygen concentration versus a thickness of the semiconductor device 100A.

In the exemplary illustration of FIGS. 1B and 1C, the oxynitride dielectric layer 122 includes aluminum oxynitride (AlON). In the exemplary illustration of FIGS. 1B and 1C, the passivation layer 124 includes silicon nitride (Si₃N₄). In the exemplary illustration of FIGS. 1B and 1C, the oxynitride dielectric layer 126 includes silicon oxynitride (SiON). In the exemplary illustration of FIGS. 1B and 1C, the passivation layer 128 includes silicon nitride (Si₃N₄).

The graph shows the element content/ratio change in the semiconductor device 100A along the distance D. The elements include N, Si, Ga, Al, and O. With respect to the single element, the curve is continuous. In some embodiments, the oxynitride dielectric layer 122, the passivation layer 124, the oxynitride dielectric layer 126, and the passivation layer 128 are formed in the same chamber in sequence without vacuum break, so their EDX spectroscopy result would have the continuous curves. Such the manner is advantageous to tune the element content/ratio and is to avoid the element content/ratio from missing the desired design.

The passivation layer 124 has an oxygen concentration less than that of the oxynitride dielectric layer 122. The passivation layer 124 has the oxygen concentration less than that of the oxynitride dielectric layer 126. The passivation layer 124 has a nitrogen concentration higher than that of the oxynitride dielectric layer 122. The passivation layer 124 has the nitrogen concentration higher than that of the oxynitride dielectric layer 126. Such a configuration can allow the passivation layer 124, which is located between the oxynitride dielectric layer 122 and the oxynitride dielectric layer 126, to prevent the oxygen in the oxynitride dielectric layer 126 from diffusing to the nitride-based semiconductor layer 106.

As shown in FIG. 1C, the oxygen concentration from the passivation layer 128 to the passivation layer 124 through the oxynitride dielectric layer 126 increases and then decreases. The oxygen concentration from the passivation layer 124 to the nitride-based semiconductor layer 106 through the oxynitride dielectric layer 122 increases and then decreases. Accordingly, referring to the graph of the oxygen concentration versus the thickness, the semiconductor device 100A has an oxygen peak within the oxynitride dielectric layer 122. Herein, the phrase, “an oxygen peak within the oxynitride dielectric layer 122” means the graph has an oxygen peak P1 appearing in a distance/thinness/depth interval of the oxynitride dielectric layer 122. Moreover, the semiconductor device 100A has another oxygen peak P2 within the oxynitride dielectric layer 126.

The two peaks P1 and P2 are spaced apart by the passivation layer 124, so it can be regarded as that the passivation layer 124 can block the oxygen downward diffusing from the oxynitride dielectric layer 126. Therefore, along a vertical direction, the multilayer structure 120 can have the oxygen concentration increasing and then decreasing twice. The oxygen used in the oxynitride dielectric layer 126 may comply with the process demands or entire device design. For example, when the dielectric constant of the multilayer structure 120 needs to be tuned as being greater or less, using oxygen to form a dielectric layer is one of proper manners and thus it is required that the multilayer structure 120 would include at least one layer containing oxygen. To comply such the requirements, in some embodiments, the peak P2 may correspond to a value higher than that of the peak P1, which can achieve a proper dielectric constant and avoid oxygen diffusion. As such, no stronger oxygen peak occurs in the multilayer structure.

With respect to a semiconductor device without such the layer design, it would have one single peak. However, the single peak may correspond to an extreme single intensity. The extreme single intensity is a threat for a nitride-based channel layer.

Referring to FIG. 1B again, the passivation layer 124 is thicker than the oxynitride dielectric layers 122 and 126. The passivation layer 128 is thicker than the oxynitride dielectric layers 122 and 126. The thickness configuration is made for satisfy the requirement regarding the isolation purpose of the multilayer structure 120. The passivation layers 124 or 128 can be formed as being thick and thus is advantageous to the block if the oxygen diffusion.

Referring to FIG. 1A again, the electrodes 130 and 132 are disposed on/over/above the nitride-based semiconductor layer 106. In some embodiments, the electrode 130 can serve as a source electrode. In some embodiments, the electrode 130 can serve as a drain electrode. In some embodiments, the electrode 132 can serve as a source electrode. In some embodiments, the electrode 132 can serve as a drain electrode. In some embodiments, each of the electrodes 130 and 132 can be called a source/drain (S/D) electrode, which means they can serve as a source electrode or a drain electrode, depending on the device design.

The electrodes 130 and 132 can penetrate the multilayer structure 120 to make contact with the nitride-based semiconductor layer 106. More specifically, the electrodes 130 and 132 can penetrate the oxynitride dielectric layers 122 and 126 and the passivation layers 124 and 128 to make contact with the nitride-based semiconductor layer 106. Each of the electrodes 130 and 132 has a top portion covering the passivation layer 128. Each of the electrodes 130 and 132 can be higher than the multilayer structure 120.

In some embodiments, the electrodes 130 and 132 can include, for example but are not limited to, metals, alloys, doped semiconductor materials (such as doped crystalline silicon), compounds such as silicides and nitrides, other conductor materials, or combinations thereof. The exemplary materials of the electrodes 130 and 132 can include, for example but are not limited to, Ti, AlSi, TiN, or combinations thereof. The electrodes 130 and 132 may be a single layer, or plural layers of the same or different composition. In some embodiments, the electrodes 130 and 132 form ohmic contacts with the nitride-based semiconductor layer 106. The ohmic contacts can be achieved by applying Ti, Al, or other suitable materials to the electrodes 130 and 132. In some embodiments, each of the electrodes 130 and 132 is formed by at least one conformal layer and a conductive filling. The conformal layer can wrap the conductive filling. The exemplary materials of the conformal layer, for example but are not limited to, Ti, Ta, TiN, Al, Au, AlSi, Ni, Pt, or combinations thereof. The exemplary materials of the conductive filling can include, for example but are not limited to, AlSi, AlCu, or combinations thereof.

The doped nitride-based semiconductor layer 110 and the gate electrode 112 are located between the electrodes 130 and 132. That is, the electrodes 130 and 132 can be located at two opposite sides of the gate electrode 112, respectively. In some embodiments, other configurations may be used, particularly when plural source, drain, or gate electrodes are employed in the device. In the exemplary illustration of FIG. 1A, the electrodes 130 and 132 are symmetrical about the gate electrode 112. In other embodiments, the electrodes 130 and 132 are asymmetrical about the gate electrode 112. For example, the electrode 130 can be closer to the gate electrode 112 than the electrode 132.

The passivation layer 140 covers the multilayer structure 120 and the electrodes 130 and 132. The passivation layer 140 can be formed for a protection purpose or for enhancing the electrical properties of the device (e.g., by providing an electrical isolation effect between/among different layers/elements). The passivation layer 140 can serve as a planarization layer which has a level top surface to support other layers/elements. In some embodiments, the passivation layer 140 can be formed as a thicker layer, and a planarization process, such as chemical mechanical polish (CMP) process, is performed on the passivation layer 140 to remove the excess portions, thereby forming a level top surface. The exemplary materials of the passivation layer 140 can include, for example but are not limited to, SiNₓ, SiOₓ, Si₃N₄, SiON, SiC, SiBN, SiCBN, oxides, nitrides, plasma-enhanced oxide (PEOX), or combinations thereof. In some embodiments, the passivation layer 140 can be a multi-layered structure, such as a composite dielectric layer of Al₂O₃/SiN, Al₂O₃/SiO₂, AlN/SiN, AlN/SiO₂, or combinations thereof.

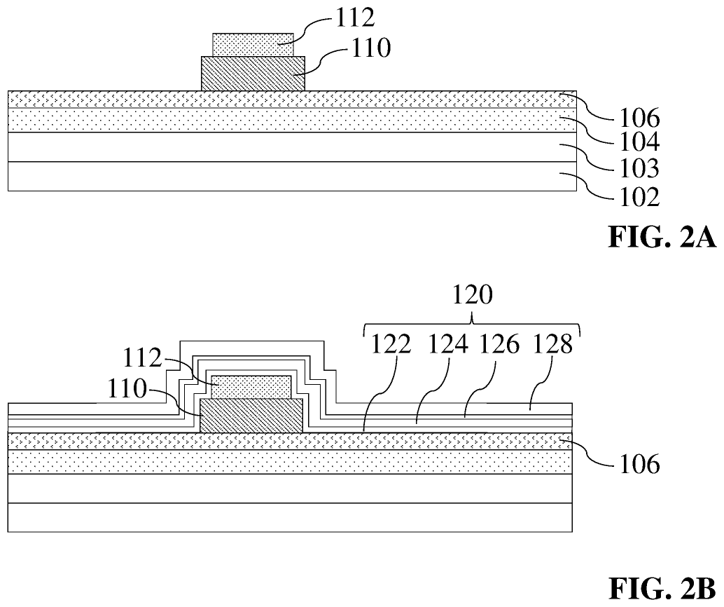

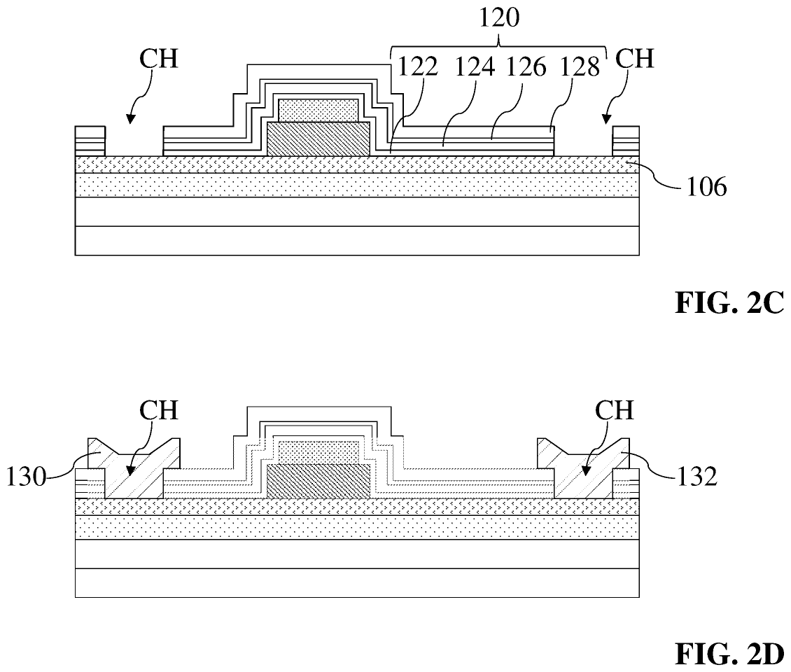

Different stages of a method for manufacturing the semiconductor device 100A are shown in FIG. 2A, FIG. 2B, FIG. 2C, and FIG. 2D, as described below. In the following, deposition techniques can include, for example but are not limited to, atomic layer deposition (ALD), physical vapor deposition (PVD), chemical vapor deposition (CVD), metal organic CVD (MOCVD), plasma enhanced CVD (PECVD), low-pressure CVD (LPCVD), plasma-assisted vapor deposition, epitaxial growth, or other suitable processes.

Referring to FIG. 2A, a substrate 102 is provided. A buffer layer 103, nitride-based semiconductor layers 104, 106 can be formed over the substrate 102 in sequence by using deposition techniques. To be more specific, the buffer layer 103 is formed on a substrate 102. The nitride-based semiconductor layer 104 is formed on the buffer layer 103. The nitride-based semiconductor layer 106 is formed on the nitride-based semiconductor layer 104. Thereafter, a doped nitride-based semiconductor layer 110 and a gate electrode 112 can be formed over the nitride-based semiconductor layer 106. The formation of the doped nitride-based semiconductor layer 110 and the gate electrode 112 includes deposition techniques and a patterning process. In some embodiments, the deposition techniques can be performed for forming a blanket layer, and the patterning process can be performed for removing excess portions thereof. In some embodiments, the patterning process can include photolithography, exposure and development, etching, other suitable processes, or combinations thereof.

Referring to FIG. 2B, a multilayer structure 120 can be formed/deposited over the nitride-based semiconductor layer 106. The multilayer structure 120 covers the doped nitride-based semiconductor layer 110 and the gate electrode 112. The formation of the includes forming an oxynitride dielectric layer 122, a passivation layer 124, an oxynitride dielectric layer 126, and a passivation layer 128 in sequence.

The oxynitride dielectric layer 122 is formed on the nitride-based semiconductor layer 106. The oxynitride dielectric layer 122 can conformally cover the nitride-based semiconductor layer 106, the doped nitride-based semiconductor layer 110, and the gate electrode 112. The passivation layer 124 is conformally formed on the oxynitride dielectric layer 122. The oxynitride dielectric layer 126 is formed on the passivation layer 124. The passivation layer 128 is formed on the oxynitride dielectric layer 126. These layers can be formed in the same chamber by changing different gas sources, and thus each of the element concentrations of the multilayer structure 120 is continuous, as shown in FIG. 1C.

Referring to FIG. 2C, portions of the oxynitride dielectric layers 122 and 126 and the passivation layers 124 and 128 are removed to form ohmic contact holes CH. Portions of the nitride-based semiconductor layer 106 are exposed from the ohmic contact holes CH. In some embodiments, the removal of the oxynitride dielectric layers 122 and 126 and the passivation layers 124 and 128 include an etching process.

Referring to FIG. 2D, the ohmic contact holes CH are filled with electrodes 130 and 132, respectively. Thereafter, a passivation layer can be formed to cover the resultant structure, obtaining the configuration of the semiconductor device 100A as shown in FIG. 1A.

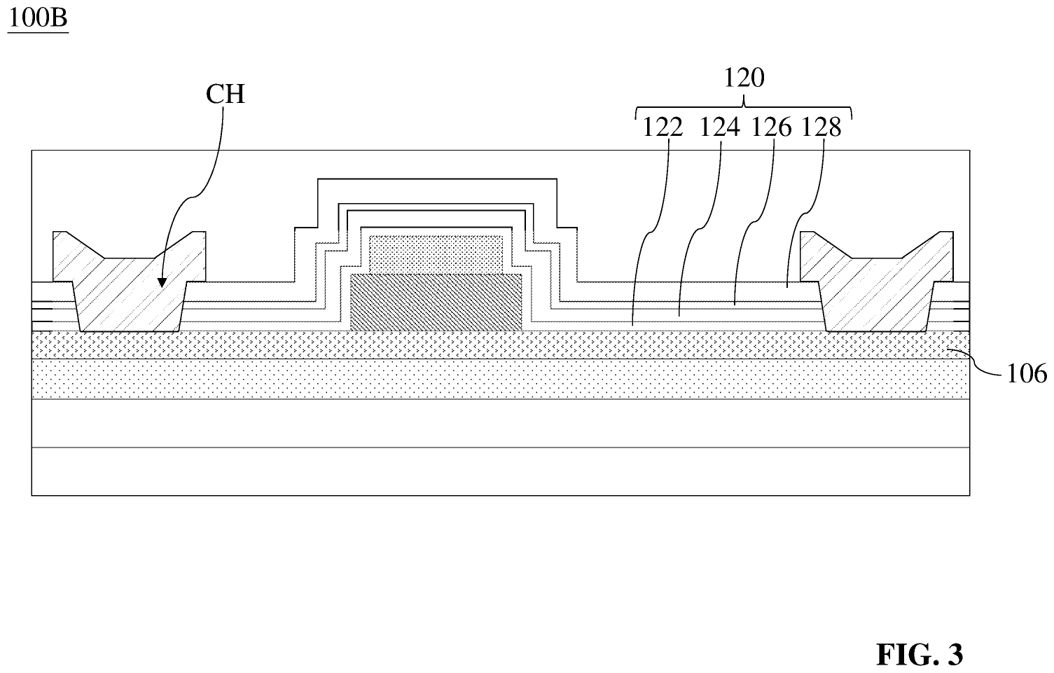

FIG. 3 is a cross-sectional view of a semiconductor device 100B according to some embodiments of the present disclosure. In the exemplary illustration of FIG. 3, in the multilayer structure 120, the oxynitride dielectric layer 122, the passivation layer 124, the oxynitride dielectric layer 126, and the passivation layer 128 have different composition so they would have different etching rates with respect to the same etch etchant. Therefore, sidewalls of the ohmic contact holes CH are oblique with respect to the nitride-based semiconductor layer 106.

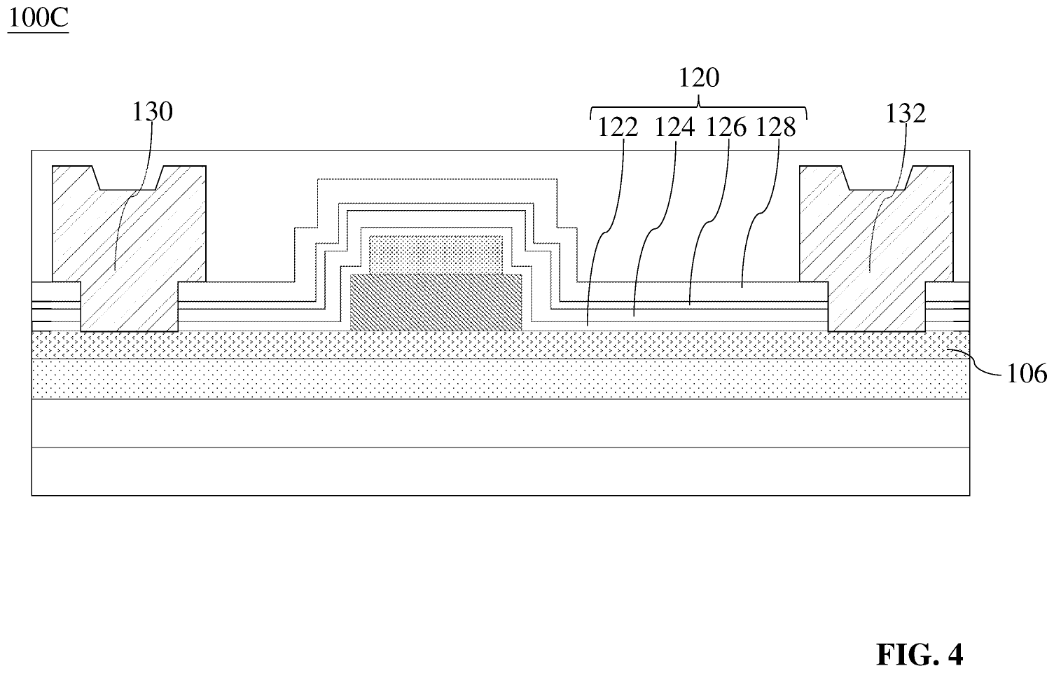

FIG. 4 is a cross-sectional view of a semiconductor device 100C according to some embodiments of the present disclosure. In the exemplary illustration of FIG. 4, the multilayer structure 120 has a height less than the electrodes 130 and 132 with respect to the nitride-based semiconductor layer 106. The height relationship among the multilayer structure 120 and the electrodes 130 and 132 are selectable, which means the manufacturing process for the semiconductor devices of the present disclosure has high compatibility.

It should be noted that the above semiconductor devices can be manufactured by the afore-mentioned different processes in order to meet different electrical requirements.

Based on the above descriptions, in the present disclosure, the semiconductor device is provided with a multilayer structure including at least two dielectric protection layers. The dielectric protection layer in contact with the gate electrode and the doped nitride-based semiconductor layer has a lower oxygen concentration and is thinner than another one dielectric protection layer, such that a good protection to the gate electrode and the doped nitride-based semiconductor layer is achieved. Accordingly, the semiconductor device of the present disclosure can have good electrical properties and reliability.

The embodiments were chosen and described in order to best explain the principles of the disclosure and its practical application, thereby enabling others skilled in the art to understand the disclosure for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the FIGS. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A nitride-based semiconductor device comprising:
a first nitride-based semiconductor layer;
a second nitride-based semiconductor layer disposed on the first nitride-based semiconductor layer and having a bandgap greater than a bandgap of the first nitride-based semiconductor layer;
a doped nitride-based semiconductor layer disposed over the second nitride-based semiconductor layer;
a gate electrode disposed on the doped nitride-based semiconductor layer to form a protruding profile with the doped nitride-based semiconductor layer;
a first oxynitride dielectric layer disposed over the second nitride-based semiconductor layer and conformally covers the doped nitride-based semiconductor layer and the gate electrode;
a first passivation layer disposed on the first oxynitride dielectric layer and in contact with the first oxynitride dielectric layer;
a second oxynitride dielectric layer disposed on the first passivation layer and in contact with the first passivation layer;
a second passivation layer disposed on the second oxynitride dielectric layer and in contact with the second oxynitride dielectric layer; and
a source/drain (S/D) electrode penetrating the first and second oxynitride dielectric layers and the first and second passivation layers to make contact with the second nitride-based semiconductor layer.

2. The semiconductor device of claim 1, wherein an oxygen concentration from the first passivation layer to the second nitride-based semiconductor layer through the first oxynitride dielectric layer increases and then decreases.

3. The semiconductor device of claim 2, wherein a graph of the oxygen concentration versus a thickness of the semiconductor device has a peak in the first oxynitride dielectric layer.

4. The semiconductor device of claim 1, wherein an oxygen concentration from the second passivation layer to the first passivation layer through the second oxynitride dielectric layer increases and then decreases.

5. The semiconductor device of claim 4, wherein a graph of the oxygen concentration versus a thickness of the semiconductor device has a peak in the second oxynitride dielectric layer.

6. The semiconductor device of claim 1, wherein the first passivation layer has an oxygen concentration less than those of the first and second oxynitride dielectric layers.

7. The semiconductor device of claim 6, wherein the first passivation layer has a nitrogen concentration higher than those of the first and second oxynitride dielectric layers.

8. The semiconductor device of claim 1, wherein the second passivation layer has an oxygen concentration less than those of the first and second oxynitride dielectric layers.

9. The semiconductor device of claim 6, wherein the second passivation layer has a nitrogen concentration higher than those of the first and second oxynitride dielectric layers.

10. The semiconductor device of claim 1, wherein the first passivation layer is thicker than the first and second oxynitride dielectric layers.

11. The semiconductor device of claim 1, wherein the second passivation layer is thicker than the first and second oxynitride dielectric layers.

12. The semiconductor device of claim 1, wherein the second passivation layer is thicker than the first passivation layer.

13. The semiconductor device of claim 1, wherein the S/D electrode has a top portion covering the second passivation layer.

14. The semiconductor device of claim 1, wherein the first oxynitride dielectric layer comprises aluminum oxynitride (AlON), and the second oxynitride dielectric layer comprises silicon oxynitride (SiON).

15. The semiconductor device of claim 14, wherein the first and second passivation each comprise silicon nitride (Si₃N₄).

16. A manufacturing method of a semiconductor device, comprising:
forming a first nitride-based semiconductor layer;
forming a second nitride-based semiconductor layer on the first nitride-based semiconductor layer;
forming a doped nitride-based semiconductor layer over the second nitride-based semiconductor layer;
forming a gate electrode on the doped nitride-based semiconductor layer;
forming a first oxynitride dielectric layer on the second nitride-based semiconductor layer to conformally cover the second nitride-based semiconductor layer, the doped nitride-based semiconductor layer, and the gate electrode;
forming a first passivation layer conformally on the first oxynitride dielectric layer;
forming a second oxynitride dielectric layer on the first passivation layer;
forming a second passivation layer on the second oxynitride dielectric layer;
removing portions of the first and second oxynitride dielectric layers and first and second passivation layers to form an ohmic contact hole which exposes the second nitride-based semiconductor layer; and
filling the ohmic contact hole with a source/drain (S/D) electrode.

17. The manufacturing method of claim 16, wherein a graph of an oxygen concentration versus a thickness of the semiconductor device has a first peak in the first oxynitride dielectric layer.

18. The manufacturing method of claim 17, wherein the graph has a second peak in the second oxynitride dielectric layer.

19. The manufacturing method of claim 16, wherein the first oxynitride dielectric layer comprises aluminium oxynitride (AlON), and the second oxynitride dielectric layer comprises silicon oxynitride (SiON).

20. The manufacturing method of claim 1, wherein the first and second passivation each comprise silicon nitride (Si₃N₄).

21-25. (canceled)
